(19) United States
(12) Patent Application Publication
(10) Pub. No.: US 2024/0147697 A1
(43) Pub. Date: May 2, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Yanghee LEE, Suwon-si (KR); Byoungho KWON, Suwon-si (KR); Seongeun KIM, Suwon-si (KR); Sujeong KIM, Suwon-si (KR); Jonghyuk PARK, Suwon-si (KR); Ilyoung YOON, Suwon-si (KR); Woohyuk JANG, Suwon-si (KR); Byungsoo JOO, Suwon-si (KR)

(21) Appl. No.: 18/308,376

(22) Filed: Apr. 27, 2023

(30) Foreign Application Priority Data
Oct. 31, 2022 (KR) 10-2022-0142978

(51) Int. Cl. H10B 12/00

(52) U.S. Cl. CPC H10B 12/315; H10B 12/0335; H10B 12/09; H10B 12/482

(57) ABSTRACT

A semiconductor device includes a substrate, a chip region in the substrate, a scribe lane region in the substrate, first active patterns in the chip region, a first device isolation pattern on the first active patterns, second active patterns in the scribe lane region, and a second device isolation pattern on the second active patterns. The scribe lane region is adjacent to the chip region. The first device isolation pattern includes a first device isolation material, and the second device isolation pattern includes a second device isolation material. The second device isolation material is different from the first device isolation material.

### CROSS-REFERENCE TO RELATED APPLICATION

This application claims priority to and the benefit of Korean Patent Application No. 10-2022-0142978 filed in the Korean Intellectual Property Office on Oct. 31, 2022, the entire contents of which are incorporated herein by reference.

### BACKGROUND

The present disclosure relates to a semiconductor device and a method of fabricating the same, and more particularly, to a DRAM device and a method of fabricating the same.

In the DRAM device, structures formed in a chip region may be formed by using an overlay key formed in a scribe lane region. The overlay key may consist of key structures and a trench formed therebetween.

However, the structures in the chip region may be formed through a poly etch back process, during which silicon (Si) is also recessed under the trench, resulting in an abnormal recess.

### SUMMARY

One aspect of the present disclosure provides a semiconductor device which improves an abnormal recess in a lower portion of a trench between key structures and does not generate corrosion of a key region (key erosion) due to an increase in oxide density during chemical mechanical polishing (CMP) for forming a device isolation pattern.

According to some embodiments, a semiconductor may comprise a substrate; a chip region in the substrate; a scribe lane region in the substrate; first active patterns in the chip region; a first device isolation pattern on the first active patterns; second active patterns in the scribe lane region; and a second device isolation pattern on the second active patterns, wherein the scribe lane region may be adjacent to the chip region, wherein the first device isolation pattern may include a first device isolation material, wherein the second device isolation pattern may include a second device isolation material, and wherein the second device isolation material may be different from the first device isolation material.

According to some embodiments, the first device isolation material may have a first etching rate, the second device isolation material may have a second etching rate, and the first etching rate may be different from the second etching rate.

According to some embodiments, the second etching rate may be less than or equal to 0.1 times of the first etching rate.

According to some embodiments, the first device isolation material may include silicon oxide, and the second device isolation material may include silicon nitride, silicon carbon nitride, silicon boron nitride, silicon carbon boron nitride, polysilicon, doped polysilicon, and/or a mixture thereof.

According to some embodiments, the semiconductor device may further comprise bit line structures in the chip region and key structures in the scribe lane region.

According to some embodiments, the bit line structures may include a first conductive structure, a first barrier pattern, a first metal pattern, and a first capping pattern which may be stacked on the substrate.

According to some embodiments, the key structures may include an insulation pattern, a second conductive structure, a second barrier pattern, a second metal pattern, and a second capping pattern which may be stacked on the substrate.

According to some embodiments, the bit line structures may be spaced apart from each other by a first width in a first direction parallel to an upper surface of the substrate and may extend in a second direction that intersects the first direction.

According to some embodiments, the key structures may be spaced apart from each other by a second width in the first direction parallel to the upper surface of the substrate and may extend in the second direction.

According to some embodiments, the second width may be greater than the first width.

A semiconductor device according to some embodiments may comprise a substrate that has a chip region and a scribe lane region that surrounds the chip region in a plan view, wherein the chip region includes first active patterns, a first device isolation pattern on the first active patterns, and first gate structures on respective ones of the first active patterns and on the first device isolation pattern, wherein the scribe lane region includes second active patterns and a second device isolation pattern on the second active patterns, wherein the first device isolation pattern includes a first device isolation material, wherein the second device isolation pattern includes a second device isolation material, and wherein the second device isolation material has an etch selectivity with respect to the first device isolation material.

According to some embodiments, the first gate structures each may include a first gate insulation layer on the first active patterns and the substrate, a first gate electrode on the first gate insulation layer, and a first gate mask on the first gate electrode.

According to some embodiments, the first gate structures may extend in a first direction parallel to an upper surface of the substrate and may be spaced apart from each other in a second direction that intersects the first direction.

According to some embodiments, a semiconductor device may comprise a substrate that has a chip region, and a scribe lane region that surrounds the chip region in a plan view; bit line structures on the chip region; and key structures on the scribe lane region, wherein the chip region includes first active patterns, a first device isolation pattern between the first active patterns, and first gate structures on respective ones of the first active patterns and on the first device isolation pattern, wherein the scribe lane region includes second active patterns and a second device isolation pattern between the second active patterns, wherein the first device isolation pattern includes a first device isolation material, wherein the second device isolation pattern includes a second device isolation material, and wherein the second device isolation material has an etch selectivity with respect to the first device isolation material.

According to some embodiments, the bit line structures may be spaced apart from each other by a first width in a first direction parallel to an upper surface of the substrate and may extend in a second direction that intersects the first direction.

According to some embodiments, the key structures may be spaced apart from each other by a second width in a first direction parallel to an upper surface of the substrate and may extend in a second direction that intersects the first direction.

According to some embodiments, the first gate structures may extend in a first direction parallel to an upper surface of the substrate and may be spaced apart from each other in a second direction that intersects the first direction.

According to some embodiments, the semiconductor device may further comprise a lower contact plug on a respective one of the first active patterns and the first device isolation pattern between the bit line structures; and an upper contact plug on the lower contact plug.

According to some embodiments, the semiconductor device may further comprise a fill pattern on the second device isolation pattern between the key structures and an upper contact layer on the second active patterns and the key structures.

According to some embodiments, the semiconductor device may further comprise a capacitor on the upper contact plug, wherein the capacitor includes a lower electrode on the upper contact plug, a dielectric layer on the lower electrode, and an upper electrode on the dielectric layer.

A method of fabricating a semiconductor device includes forming second active patterns spaced apart from each other by trenches on a scribe lane region of a substrate having a chip region and a scribe lane region surrounding the chip region, forming a second device isolation pattern between the second active patterns, forming first active patterns spaced apart from each other by openings on a chip region of the substrate, and forming a first device isolation pattern between the first active patterns, wherein the first device isolation pattern includes a first device isolation material, the second device isolation pattern includes a second device isolation material, and the second device isolation material has etch selectivity with respect to the first device isolation material.

The second device isolation material may have etch selectivity with respect to the first device isolation material when forming the first device isolation pattern.

The etch selectivity of the second device isolation material to the first device isolation material (r=etching rate of the second device isolation material/etching rate of the first device isolation material) may be less than or equal to about 0.1.

The first device isolation material may include a silicon oxide.

The second device isolation material may include a silicon nitride (SiN), a silicon carbon nitride (SiCN), a silicon boron nitride (SiBN), a silicon carbon boron nitride (SiCBN), a polysilicon, a doped polysilicon, or a mixture thereof.

The second device isolation pattern may be formed by forming a second device isolation layer filling the trench on the second active pattern and planarizing the second device isolation layer until a top surface of the second active pattern is exposed.

The first device isolation pattern may be formed by forming a first device isolation layer configured to fill the opening on the first active pattern and planarizing the first device isolation layer until a top surface of the first active pattern is exposed.

Bit line structures may be formed on the chip region of the substrate, and key structures may be formed on the scribe lane region of the substrate.

After forming a first liner layer on the surface of the first active pattern, a first device isolation layer configured to fill the opening may be formed on the first active pattern.

The first liner layer may include a silicon nitride (SiN), a silicon carbon nitride (SiCN), a silicon boron nitride (SiBN), a silicon carbon boron nitride (SiCBN), or a mixture thereof.

According to the semiconductor device according to one aspect, while improving an abnormal recess in a lower portion of a trench between key structures, corrosion of a key region (key erosion) due to an increase in oxide density during chemical mechanical polishing (CMP) for forming a device isolation pattern does not occur.

### BRIEF DESCRIPTION OF THE DRAWINGS

FIG. 1 is a plan view of a semiconductor device according to some embodiments.

FIG. 2 is an enlarged plan view of the X region of FIG. 1.

FIG. 3 is a plan view of the Y region of FIG. 2 showing a method of fabricating a semiconductor device.

FIG. 4 are cross-sectional views showing a method of fabricating a semiconductor device, respectively, taken along line A-A′ and line B-B′ of the Y region of the corresponding plan view.

FIG. 5 is a cross-sectional view showing a method of fabricating a semiconductor device, taken along line D-D′ of the W region of the corresponding plan view.

FIG. 6 are cross-sectional views showing a method of fabricating a semiconductor device, respectively, taken along line A-A′ and line B-B′ of the Y region of the corresponding plan view.

FIG. 7 is a cross-sectional view showing a method of fabricating a semiconductor device, taken along line D-D′ of the W region of the corresponding plan view.

FIG. 8 are cross-sectional views showing a method of fabricating a semiconductor device, respectively, taken along line A-A′ and line B-B′ of the Y region of the corresponding plan view.

FIG. 9 is a cross-sectional view showing a method of fabricating a semiconductor device, taken along line D-D′ of the W region of the corresponding plan view.

FIG. 10 are cross-sectional views showing a method of fabricating a semiconductor device, respectively, taken along line A-A′ and line B-B′ of the Y region of the corresponding plan view.

FIG. 11 is a cross-sectional view showing a method of fabricating a semiconductor device, taken along line D-D′ of the W region of the corresponding plan view.

FIG. 12 are cross-sectional views showing a method of fabricating a semiconductor device, respectively, taken along line A-A′ and line B-B′ of the Y region of the corresponding plan view.

FIG. 13 is a cross-sectional view showing a method of fabricating a semiconductor device, taken along line D-D′ of the W region of the corresponding plan view.

FIG. 14 are cross-sectional views showing a method of fabricating a semiconductor device, respectively, taken along line A-A′ and line B-B′ of the Y region of the corresponding plan view.

FIG. 15 is a cross-sectional view showing a method of fabricating a semiconductor device, taken along line D-D′ of the W region of the corresponding plan view.

FIG. 16 is a plan view of the Y region of FIG. 2.

FIG. 17 are cross-sectional views of the Y region of the corresponding plan view taken along line A-A′ and line B-B′.

FIG. 18 is a cross-sectional view taken along line D-D′ of the W region of the corresponding plan view.

### DETAILED DESCRIPTION

The present disclosure will be described more fully hereinafter with reference to the accompanying drawings, in which embodiments of the invention are shown. The drawings and description are to be regarded as illustrative in nature and not restrictive. Like reference numerals designate like elements throughout the specification. Further, the accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

It should also be noted that in some alternate implementations, the methods, processes, and operations may occur out of the order described herein. For example, two processes described in succession may in fact be executed substantially concurrently or in reverse order. Also, other methods, processes, and operations may be added/inserted between the methods, processes, and operations described herein and/or be omitted without departing from the scope of the present invention.

Terms including ordinal numbers such as first, second, and the like will be used only to describe various constituent elements and are not to be interpreted as limiting these constituent elements. The terms are only used to differentiate one constituent element from other constituent elements.

It is to be understood that when one constituent element is referred to as being “connected” or “coupled” to another constituent element, it may be connected or coupled directly to the other constituent element or may be connected or coupled to the other constituent element with a further constituent element intervening therebetween. In contrast, it should be understood that, when it is described that an element is “directly coupled” or “directly connected” to another element, no element is present between the element and the other element.

Throughout the specification, it should be understood that the term “include,” “comprise,” or “have” indicates that a feature, a number, a step, an operation, a constituent element, a part, or a combination thereof described in the specification is present but does not exclude a possibility of presence or addition of one or more other features, numbers, steps, operations, constituent elements, parts, or combinations, in advance. Unless explicitly described to the contrary, the word “comprise” and variations such as “comprises” or “comprising” will be understood to imply the inclusion of stated elements but not the exclusion of any other elements.

When materials, layers (films), regions, pads, electrodes, patterns, structures, or processes are referred to herein as “first,” “second,” and/or “third,” it is not intended to limit such members. rather than merely distinguishing each material, layer (film), region, electrode, pad, pattern, structure, and process. Thus, “first,” “second,” and/or “third” may be used selectively or interchangeably with respect to each material, layer (film), region, electrode, pad, pattern, structure, and process, respectively. For example, a first element could be termed a second element without departing from the teachings of the present embodiments.

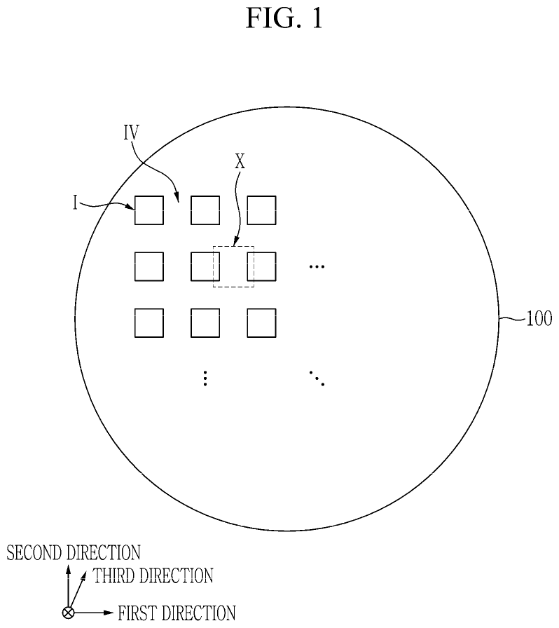

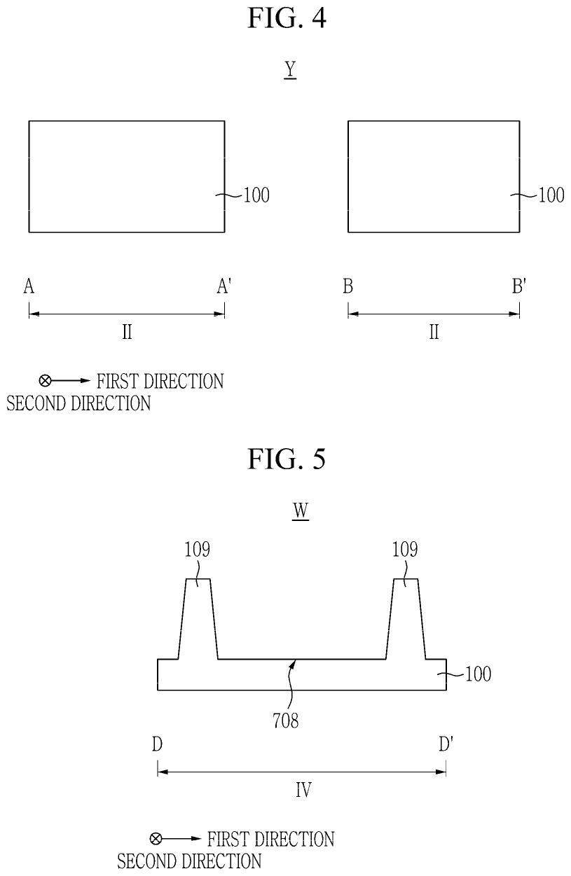

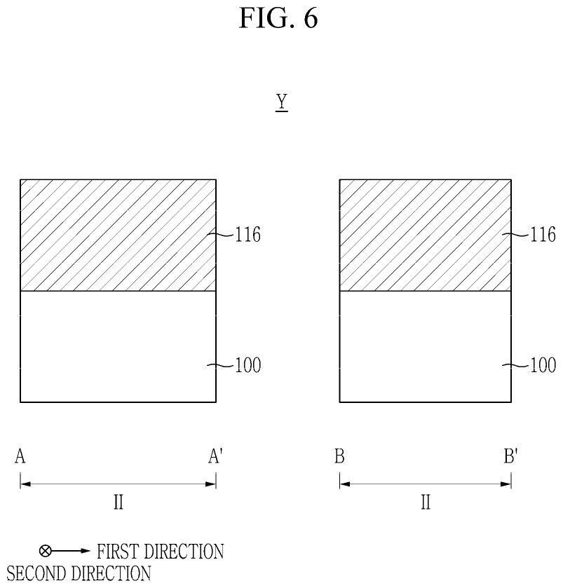

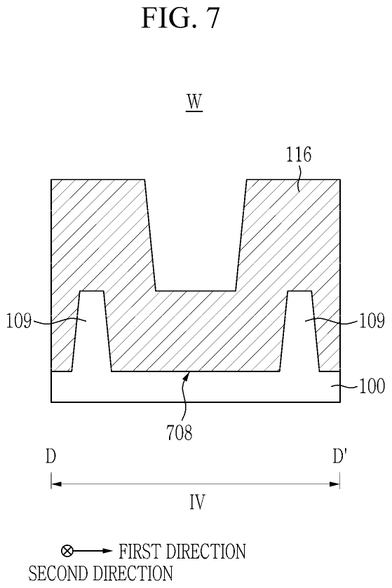

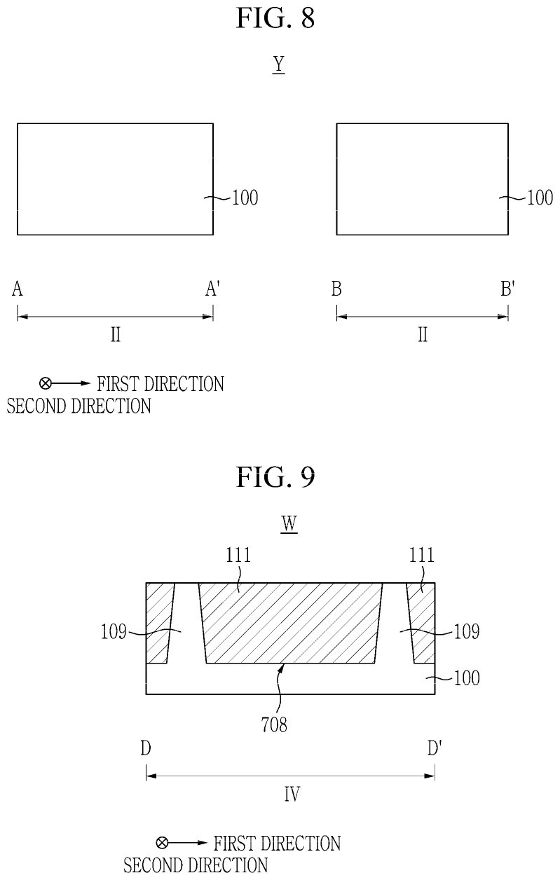

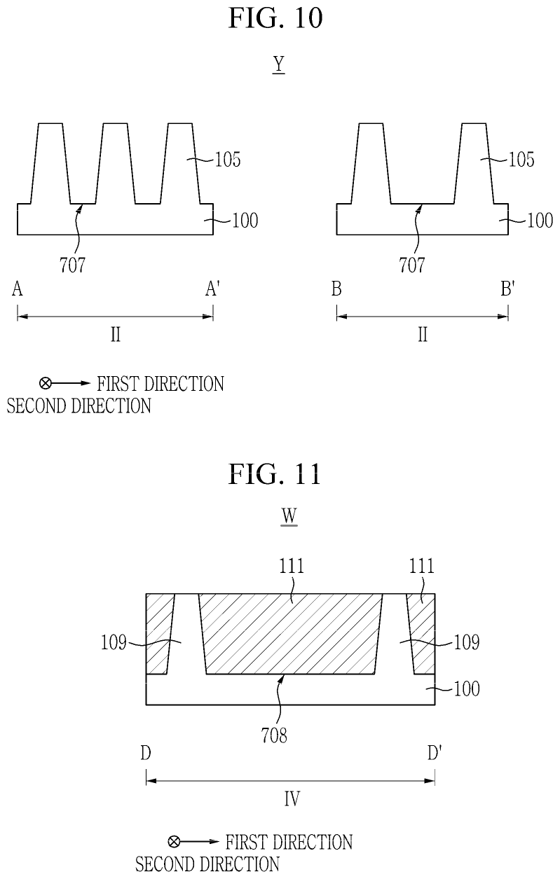

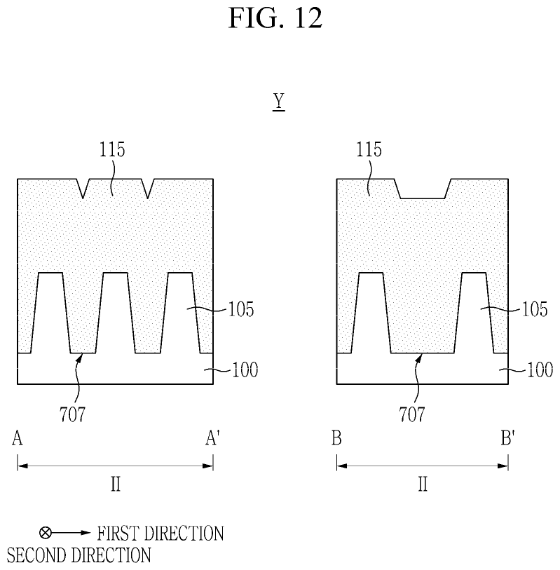

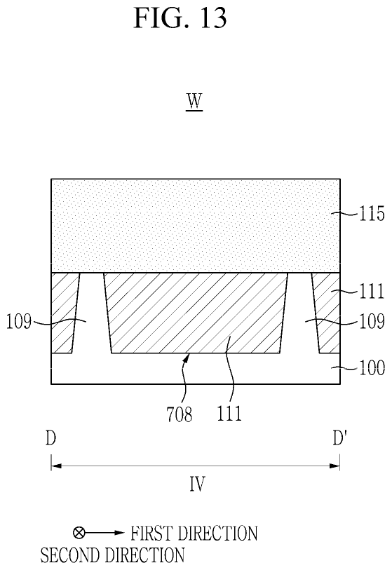

FIGS. 1 to 18 are plan views and cross-sectional views illustrating a method of fabricating a semiconductor device according to embodiments. FIGS. 1 to 3 and 16 are plan views, and FIGS. 4 to 15, 17, and 18 are cross-sectional views.

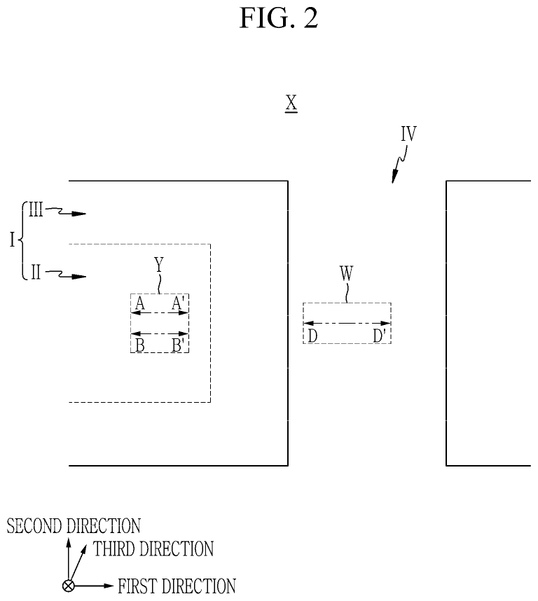

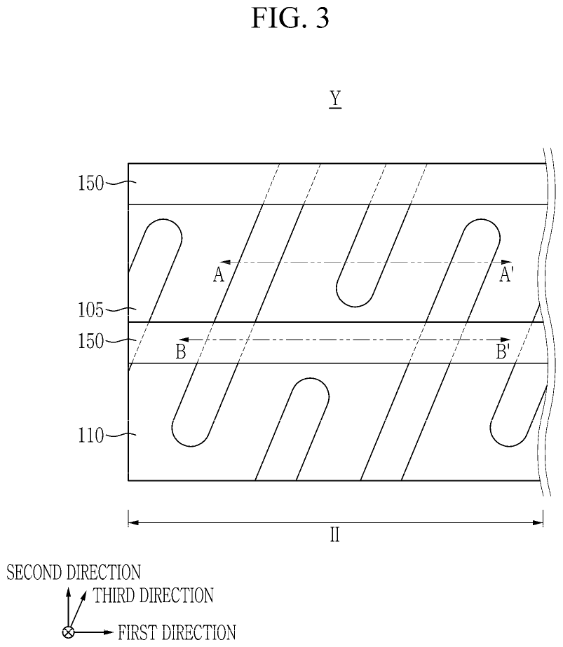

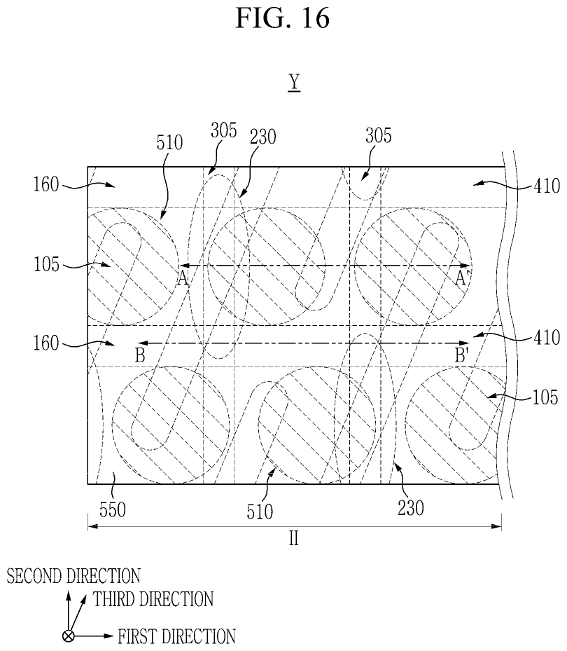

FIG. 2 is an enlarged plan view of the X region of FIG. 1, FIGS. 3 and 16 are plan views of the Y region of FIG. 2, FIGS. 4, 6, 8, 10, 12, 14, and 17 includes cross-sections taken along line A-A′ and line B-B′ of the Y regions of corresponding plan views, and FIGS. 5, 7, 9, 11, 13, 15, and 18 includes cross-sections taken along line D-D′ of the W regions of the corresponding plan views. FIGS. 3 to 15 show each step of fabricating a semiconductor device.

In the detailed description of the embodiments below, two directions parallel to the upper surface of a substrate 100 and orthogonal to each other are defined as first and second directions, respectively, and also a direction parallel to the upper surface of the substrate 100 and forming an acute angle with each of the first and second directions is defined as a third direction. For example, the first direction may intersect the second direction.

Referring to FIGS. 1 and 2, the substrate 100 may include first and fourth regions I and IV, and the first region I may include second and third regions II and III.

The substrate 100 may be, for example, a semiconductor wafer including silicon, germanium, silicon-germanium, or a Group III-V compound such as GaP, GaAs, and GaSb. According to some embodiments, the substrate 100 may be a silicon on insulator (SOI) wafer or a germanium on insulator (GOI) wafer, but not limited thereto.

The first region I of the substrate 100 may be a chip region where patterns constituting a semiconductor chip are formed. In example embodiments, a plurality of first regions I may be formed to be spaced apart from each other along the first and second directions.

Each first region I may include a second region II and a third region III. The second region II may be a cell region where memory cells are formed. The third region III may be a peripheral circuit region which surrounds the second region II and in which peripheral circuit patterns driving the memory cells are formed.

A fourth region IV of the substrate 100 may be formed between the first regions I. For example, the fourth region IV may be adjacent to the first regions I. The fourth region IV may be referred to as a scribe lane region, which may be provided to separate the chip regions (e.g., first regions I) formed on the substrate 100 by chip cutting and/or chip sawing. For example, the scribe lane region (e.g., fourth region IV) may surround the chip region (e.g., first region I) in a plan view. According to example embodiments, in the fourth region IV of the substrate 100, TEG (Test Element Group) for testing electrical characteristics and defects of various devices and an alignment key for alignment in the photolithography process or an overlay key may be formed. Herein, the alignment key may refer to a key used to precisely align an exposure mask used in the photolithography process on the substrate 100, and the overlay key may refer to a key used for measuring an overlay state between a material pattern formed on the substrate 100 and a photoresist pattern formed thereon and correcting the overlay and misalignment.

Hereinafter, a case of forming the overlay key in a W region included in the fourth region IV of the substrate 100 is illustrated, but the present disclosure is not necessarily limited thereto, and may include a case of forming the alignment key in the W region.

Referring to FIGS. 3 to 15, first and second active patterns 105 and 109 may be respectively formed on the second and fourth regions II and IV of the substrate 100, and first and second device isolation patterns 110 and 111 may be respectively on (formed to cover) sidewalls of the first and second active patterns 105 and 109.

Specifically, in the second region II of the substrate 100, the first device isolation pattern 110 may be between the first active pattern 105 and the first active pattern 105, and in the fourth region IV of the substrate 100, the second device isolation pattern 111 may be between the second active pattern 109 and the second active pattern 109. The first device isolation pattern 110 may be on the first active pattern 105. The second device isolation pattern 111 may be on the second active pattern 109.

For example, the first and second active patterns 105 and 109 may be formed by removing an upper portion of the substrate 100 to form an opening or a trench, and the first and second device isolation patterns 110 and 111 may be formed by forming an isolation layer filling the opening or the trench on the substrate 100 and planarizing the isolation layer until the upper surfaces of the first and second active patterns 105 and 109 are exposed.

However, when the planarization process to form the first and second device isolation patterns 110 and 111 is performed, silicon (Si) under the trench may be also recessed in the fourth region IV of the substrate 100 (by an excessive planarization), resulting in an abnormal recess.

In addition, when the first device isolation pattern 110 in the second region II of the substrate 100 and the second device isolation pattern 111 in the fourth region IV of the substrate 100 are filled with the same material, for example, silicon oxide, corrosion of the fourth region IV (key erosion) may occur due to an increase of field oxide density during the planarization process for forming the first and second device isolation patterns 110 and 111.

Accordingly, in example embodiments, the first device isolation pattern 110 and the second device isolation pattern 111 may not be formed in a single process but separately. In addition, the first device isolation pattern 110 and the second device isolation pattern 111 should include different materials having etch selectivity with respect to each other.

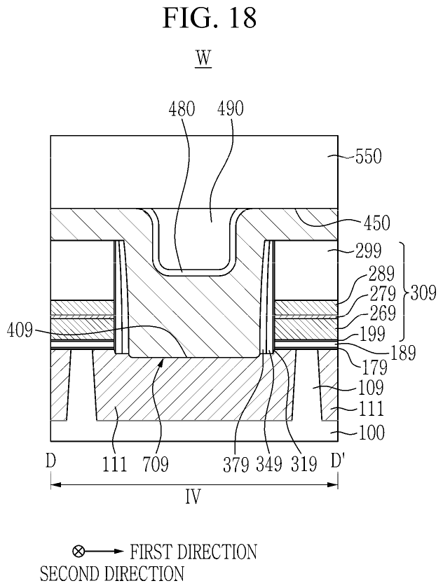

Accordingly, the semiconductor device according to example embodiments may not only improve the abnormal recess under the trench between key structures (e.g., 309 of FIG. 18) but also have less key erosion of the key region according to an increase of oxide density during the planarization process (e.g., chemical mechanical polishing (CMP)) for forming the device isolation patterns. The key structures (e.g., 309 of FIG. 18) are specifically illustrated later in FIG. 18.

Specifically, in the fourth region IV (e.g., scribe lane region) of the substrate 100, the second active patterns 109 may be formed to be spaced apart from each other by a first trench 708.

In order to conduct this, a first mask pattern may be formed on the substrate 100. The substrate 100 exposed by the first mask pattern may be etched to form the first trench 708 in the fourth region IV of the substrate 100. For example, the first mask pattern may include a silicon oxide or s silicon nitride.

The first trench 708 may have a sidewall perpendicular or substantially perpendicular to the upper surface of the substrate 100 and be formed in a plurality to extend in the third direction and to be spaced apart along the first and second directions. The first trench 708 may have a second width along the first direction.

The first trench 708 may define the second active pattern 109. Accordingly, the second active pattern 109 may include a plurality of barrier ribs extending in the third direction and spaced apart from each other along the first and second directions.

A second device isolation layer 116 filling the first trench 708 may be formed on the second active pattern 109. The second device isolation layer 116 may fill the first trench 708 and cover the substrate 100.

The second device isolation layer 116 may include a second device isolation material, and for example, the second device isolation material may include a silicon nitride (SiN), a silicon carbon nitride (SiCN), a silicon boron nitride (SiBN), a silicon carbon boron nitride (SiCBN), a polysilicon, a doped polysilicon, or a mixture thereof. The doped polysilicon may be, for example, doped with n-type dopants or p-type dopants.

The second device isolation layer 116 may be planarized, until an upper surface of the second active pattern 109 is exposed, to form the second device isolation pattern 111 between the second active patterns 109.

The second device isolation pattern 111 may fill inside the first trench 708 and be disposed between the second active patterns 109. The second device isolation pattern 111 may include the second device isolation material.

The first mask pattern may be removed during or after the planarization process (e.g., CMP process and/or etching process) of the second device isolation layer 116.

The planarization process may include a chemical mechanical polishing (CMP) process and/or an etch back process.

On the second region II in the chip region (e.g., the first region I) of the substrate 100, the first active patterns 105 spaced apart from each other by a first opening 707 may be formed.

In order to conduct this, a second mask pattern may be formed on the substrate 100. The substrate 100 exposed by the second mask pattern may be etched to form the first opening 707 in the second region II of the substrate 100. For example, the second mask pattern may include a silicon oxide or a silicon nitride.

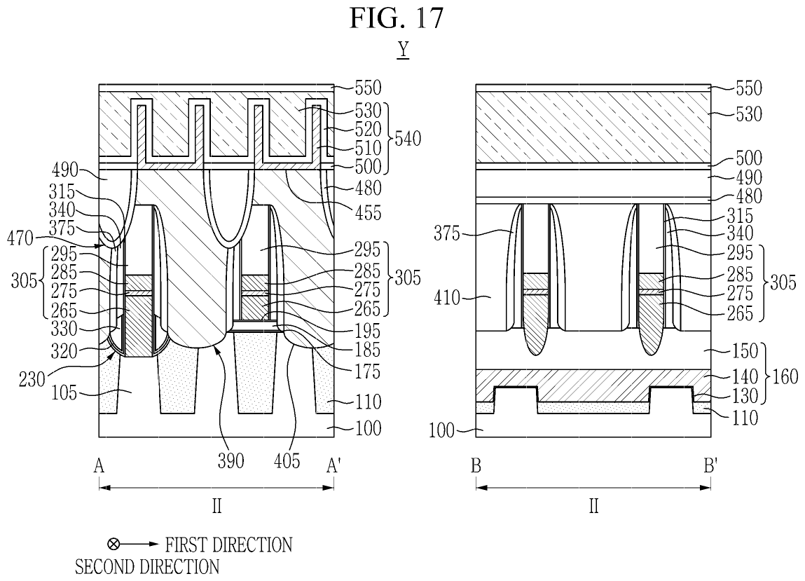

The first opening 707 may have a sidewall perpendicular or substantially perpendicular to the upper surface of the substrate 100 and be formed in a plurality to extend in the third direction and to be spaced apart along the first and second directions. The first opening 707 may have a first width along the first direction. The first width may be smaller than the second width of the first trench 708. In other words, a distance between the second active patterns 109 may be larger than a distance between the first active patterns 105 in the first direction. Subsequently, as bit line structures (e.g., 305 of FIG. 17) may be formed on the first active pattern 105 in the chip region (e.g., first region I), and the key structures (e.g., 309 of FIG. 18) may be formed on the second active pattern 109 in the scribe lane region (e.g., fourth region IV), a distance between the key structures (e.g., 309 of FIG. 18) may be larger than a distance between the bit line structures (e.g., 305 of FIG. 17) in the first direction. The bit line structures (e.g., 305 of FIG. 17) may be specifically illustrated in FIG. 17 later.

The first opening 707 may define the first active pattern 105. Accordingly, the first active pattern 105 may include a plurality of barrier ribs extending in the third direction and spaced apart from each other in the first and second directions.

A first device isolation layer 115 filling the first opening 707 may be formed on the first active pattern 105. The first device isolation layer 115 may fill the first opening 707 and cover the substrate 100.

The first device isolation layer 115 may include, for example, a silicon oxide as a first device isolation material. The first device isolation material may be different from the second device isolation material.

In other words, the second device isolation material may be a material having etch selectivity with respect to the first device isolation material. Subsequently, when a planarizing process (e.g., poly etch back process) of the first device isolation layer 115 or a forming process of the key structures (e.g., 309 of FIG. 18) is performed, the second device isolation material may not be etched or may be etched little, which may improve the abnormal recess under the first trench 708 between the key structures (e.g., 309 of FIG. 18).

In addition, since the second device isolation material may not include silicon oxide, the key erosion of the key region (e.g., W region in the fourth region IV) according to an increase of oxide density during the planarization of the first device isolation layer 115 may be prevented or reduced.

For example, etch selectivity (etching rate of the second device isolation material/etching rate of the first device isolation material) of the second device isolation material with respect to the first device isolation material (e.g., silicon oxide) may be less than or equal to about 0.1, for example, less than or equal to about 0.05 or less than or equal to about 0.01. In other words, the etching rate of the second device isolation material may be less than or equal to 0.1 times the etching rate of the first device isolation material. Herein, the etching rate of the second device isolation material and the etching rate of the first device isolation material may be an etching rate of the second device isolation material and an etching rate of the first device isolation material in the process of planarizing the first device isolation layer 115. Etching rate herein may refer to a material characteristic. For example, the etching rate of the first device isolation material may be a material characteristic of the first device isolation material, not a method of the etching process. Likewise, the etching rate of the second device isolation material may be a material characteristic of the second device isolation material, not a method of the etching process.

The first device isolation layer 115 may be planarized, until the upper surface of the first active pattern 105 is exposed, to form the first device isolation pattern 110 between the first active patterns 105.

The first device isolation pattern 110 may fill the inside of the first opening 707 and may be disposed between the first active patterns 105. The first device isolation pattern 110 may include the first device isolation material.

The second mask pattern may be removed during or after the planarization process (e.g., CMP process and/or etching process) of the first device isolation layer 115.

The planarization process may include a chemical mechanical polishing (CMP) process and/or an etch back process.

In some embodiments, after forming a first liner layer (not shown) on the surface of the first active pattern 105, the first device isolation layer 115 filling the first opening 707 may be formed on the first active pattern 105. The first device isolation layer 115 may be formed on the first liner layer.

The first liner layer may be formed in a method of atomic layer deposition (ALD), low pressure chemical vapor deposition (LPCVD), plasma enhanced chemical vapor deposition (PECVD), plasma nitration, or the like.

The first liner layer may cover the bottom surface of the first opening 707, the sidewall of the first active pattern 105, and the upper surface of the second mask pattern.

In some embodiments, the first liner layer may include a silicon-containing nitride, for example, a silicon nitride (SiN), a silicon carbon nitride (SiCN), a silicon boron nitride (SiBN), a silicon carbon boron nitride (SiCBN), or a mixture thereof.

The first liner layer on the upper surface of the second mask pattern may be removed together with the second mask pattern during or after the planarization process (e.g., CMP process and/or etching process) of the first device isolation layer 115.

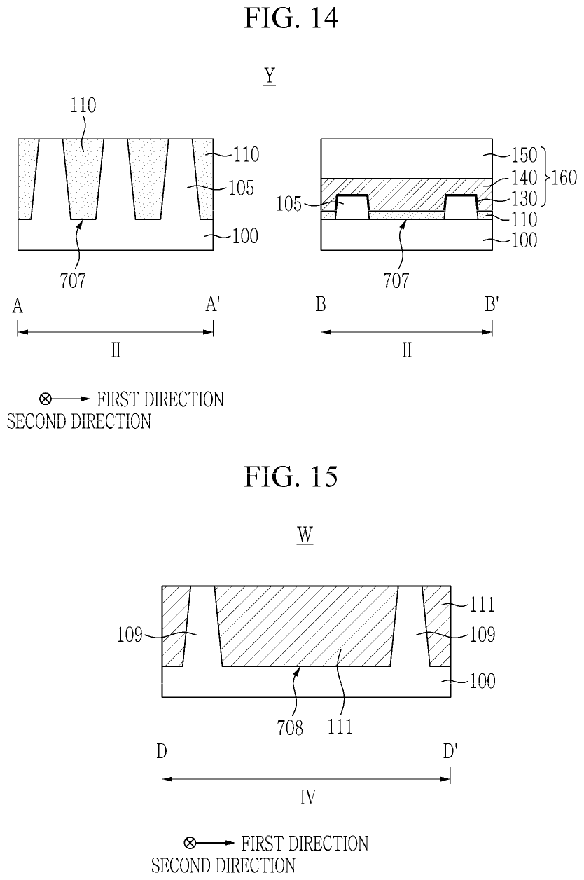

Referring to a cross-section view taken along a line B-B′ of FIG. 14, a process of forming a first gate structure 160 is illustrated.

After forming an extrinsic region (not shown) on the substrate 100 by performing an ion implantation process, the first active pattern 105 and the first device isolation pattern 110 formed in the second region II of the substrate 100 may be partially etched to form a first recess extending in a first direction, and then form the first gate structure 160 inside the first recess. The extrinsic region may include a region doped with impurities such as dopants (e.g., well region).

The first gate structure 160 may (e.g., each) include a first gate insulation layer 130 formed on the surface of the first active pattern 105 exposed by the first recess, a first gate electrode 140 formed on the first gate insulation layer 130 to fill a lower portion of the first recess, and a first gate mask 150 formed on the first gate electrode 140 to fill an upper portion of the first recess. The first gate structure 150 may be on respective ones of the first active patterns 105 and the first device isolation pattern 110. Herein, the first gate structure 160 may extend along the first direction in the first region I of the substrate 100 and also, be formed in plurality to be spaced apart from each other along the second direction.

Referring to FIGS. 16 to 18, a process of forming each bit line structure 305 and key structure 309 on the second and fourth regions II and IV of the substrate 100 is illustrated.

In the second and fourth regions II and IV of the substrate 100, an insulation layer structure may be formed on the first and second active patterns 105 and 109 and the first and second device isolation pattern 110 and 111.

The insulation layer structure may include first to third insulation layers which are (e.g., sequentially) stacked. Each first and third insulation layer may include, for example, an oxide such as a silicon oxide, and the second insulation layer may include, for example, a nitride such as a silicon nitride.

Subsequently, the first to third insulation layers may be etched to form first to third insulation patterns 175, 185, and 195 in the second region II of the substrate 100 and fourth to sixth insulation patterns 179, 189, and 199 in the fourth region (IV).

After forming a first conductive layer on the insulation layer structure and the first device isolation pattern 110, the first conductive layer and the insulation layer structure may be etched to form a second recess 230 exposing the first active pattern 105 formed on the second region II of the substrate 100. Herein, the first conductive layer may include, for example, a polysilicon doped with impurities.

A second conductive layer may be formed to fill the second recess 230. The second conductive layer may include, for example, a polysilicon doped with impurities and be thus merged with the first conductive layer.

On the first and second conductive layers, a third conductive layer, a barrier layer, and a first metal layer may be (e.g., sequentially) formed.

In example embodiments, the third conductive layer may include substantially the same material as the first and second conductive layers. In other words, the third conductive layer may include polysilicon doped with impurities and thus may be merged with the first and second conductive layers, forming a first conductive structure 265 in the second region II and a second conductive structure 269 in the fourth region IV.

The barrier layer may include, for example, a metal nitride such as a titanium nitride, a tantalum nitride, a tungsten nitride, and the like.

The first metal layer may include, for example, a metal such as tungsten, titanium, tantalum, and the like.

On the first metal layer, a capping layer may be formed. The capping layer may include, for example, a nitride such as a silicon nitride.

A portion of the capping layer formed on the second and fourth regions II and IV of the substrate 100 may be etched to form each first and second capping pattern 295 and 299, which may be used as an etching mask to (e.g., sequentially) etch the first metal layer, the barrier layer, the third conductive layer, the first and second conductive layers, and the third insulation layer.

As the etching process is performed, a first conductive structure 265, a first barrier pattern 275, a first metal pattern 285, and a first capping pattern 295 (e.g., sequentially) stacked on the first active pattern 105 and the first device isolation pattern 110 in the second recess 230 may be formed on the second region II of the substrate 100, while the third insulation pattern 195, the first conductive structure 265, the first barrier pattern 275, the first metal pattern 285, and the first capping pattern 295 (e.g., sequentially) stacked on the second insulation layer 180 of the insulation layer structure may be formed outside the second recess 230.

Hereinafter, the first conductive structure 265, the first barrier pattern 275, the first metal pattern 285, and the first capping pattern 295 (e.g., sequentially) stacked may be referred to as the bit line structure 305.

The bit line structure 305 may be formed to extend in the second direction on the second region II of the substrate 100 and in plurality to be spaced apart from each other in the first direction.

On the other hand, on the fourth region IV of the substrate 100, a sixth insulation pattern 199, a second conductive structure 269, a second barrier pattern 279, a second metal pattern 289, and a second capping pattern 299 (e.g., sequentially) stacked on a fifth insulation pattern 189 of the insulation layer structure may be formed.

Hereinafter, the (e.g., sequentially) stacked sixth insulation pattern 199, second conductive structure 269, second barrier pattern 279, second metal pattern 289, and second capping pattern 299 may be referred to as the key structure 309.

The key structure 309 may be formed to extend in the second direction on the fourth region IV of the substrate 100 and in plurality to be spaced apart from each other along the first direction. On the other hand, the upper surface of the key structure 309 may have the substantially same height as the bit line structure 305.

Between the neighboring bit line structures 305 in the first direction on the second region II of the substrate 100, a second opening may be formed to extend in the second direction to expose the upper surface of the second insulation layer 180 and to be connected to the second recess 230 and have a third width along the first direction. In addition, between the neighboring key structures 309 in the first direction on the fourth region IV of the substrate 100, a second trench 709 may be formed to extend in the second direction and to expose the upper surface of the second insulation layer 180 and have a fourth width that is larger than the third width along the first direction. In other words, a distance between the key structures 309 spaced apart from each other along the first direction may be larger than that between the bit line structures 305 spaced apart from each other along the first direction.

A first spacer layer may be formed on the bit line structure 305 and the key structure 309, and fourth and fifth insulation layers may be (e.g., sequentially) formed on the first spacer layer.

The first spacer layer may be formed to cover the sidewall of the third insulation pattern 195 under a portion of the bit line structure 305 and thus fill the second recess 230.

Subsequently, an etching process may be performed to etch the fourth and fifth insulation layers, and portions of the fourth and fifth insulation layers remaining in the second recess 230 may respectively form seventh and eighth insulation patterns 320 and 330.

After forming a second spacer layer on the exposed surface of the first spacer layer and the seventh and eighth insulation patterns 320 and 330 in the second recess 230, anisotropic etching of the second spacer layer may be performed to form a third spacer 340 covering the sidewall of the bit line structure 305 and a fourth spacer 349 covering the sidewall of the key structure 309 on the surface of the first spacer layer and on the seventh and eighth insulation patterns 320 and 330. The third and fourth spacers 340 and 349 may include, for example, an oxide such as a silicon oxide.

The first and second capping patterns 295 and 299 and the third and fourth spacers 340 and 349 may be used as etching masks to perform a dry etching process and thus etch the first spacer layer and the first and second insulation layers.

The dry etching process may remove the portion of the first spacer layer formed on the upper surfaces of the first and second capping patterns 295 and 299 and the upper surface of the second insulation layer 180 to form a first spacer 315 on the sidewall of the bit line structure 305 and a second spacer 319 on the sidewall of the key structure 309. The first and second spacers 315 and 319 may include, for example, a nitride such as a silicon nitride.

In addition, in the dry etching process, the first and second insulation layers may be partially removed and remain as the first and second insulation patterns 175 and 185 respectively under the bit line structure 305 and as the fourth and fifth insulation patterns 179 and 189 under the key structure 309. The first to third insulation patterns 175, 185, and 195 (e.g., sequentially) stacked under the bit line structure 305 may form a first insulation pattern structure, and the fourth to sixth insulation patterns 179, 189, and 199 formed under the key structure 309 may from a second insulation pattern structure.

Optionally, a fifth spacer 375 covering the sidewall of the bit line structure 305 and a sixth spacer 379 covering the sidewall of the key structure 309 may be further formed. The fifth and sixth spacers 375 and 379 may include, for example, a nitride such as a silicon nitride.

On the second region II of the substrate 100, the first, third, and fifth spacers 315, 340, and 375 (e.g., sequentially) stacked along a horizontal direction parallel to the sidewall of the bit line structure 305 and the upper surface of the substrate 100 may be referred to as a preliminary first spacer structure, and on the fourth region IV of the substrate 100, second, fourth, and sixth spacers 319, 349, and 379 (e.g., sequentially) stacked along the horizontal direction with the sidewall of the key structure 309 may be referred to as a second spacer structure.

Subsequently, an etching process may be performed by etching an upper portion of the first active pattern 105 to form a third recess 390 at the lower end of the second opening in the second region II. A lower contact layer may be formed with a sufficient height to fill the third recess 390 formed on the second region II of the substrate 100 and the second trench 709 formed on the fourth region IV of the substrate 100.

An upper portion of the lower contact layer may be planarized, until the upper surfaces of the first and second capping patterns 295 and 299 are exposed, to form a lower contact plug 405 between the bit line structures 305 and a fill pattern 409 between the key structures 309. The lower contact plug 405 may be on a respective one of the first active patterns 105 and the first device isolation pattern 110 between the bit line structures 305. The fill pattern 409 may be on the second device isolation pattern 111 between the key structures 309.

In example embodiments, the lower contact plug 405 and the fill pattern 409 respectively may extend in the second direction, and particularly, the lower contact plug 405 may be formed in plurality to be spaced apart from each other along the first direction.

A process of forming a third capping pattern is described with reference to a cross-sectional view taken along line B-B′ of FIG. 17.

The lower contact plug 405 may be etched to form a plurality of third openings extending in the first direction and spaced apart from each other in the second direction on the second region II of the substrate 100.

In example embodiments, each of the third openings may be overlapped with the first gate structure 160 in a direction perpendicular to the top surface of the substrate 100 on the second region II of the substrate 100.

A third capping pattern 410 configured to fill the third opening may be formed on the second region II of the substrate 100. The third capping pattern 410 may include, for example, a nitride such as a silicon nitride. In example embodiments, the third capping pattern 410 may extend in a first direction between the bit line structures 305 and may be formed in a plurality along a second direction.

Accordingly, on the second region II of the substrate 100, the lower contact plugs 405 extending in the second direction between the bit line structures 305 may be separated in plurality by the third capping patterns 410 to be spaced apart from each other along the second direction.

Subsequently, on the first to third capping patterns 295, 299, and 410, the first, third and fifth spacers 315, 340, and 375, the lower contact plug 405, and the fill pattern 409, an upper contact layer 450 may be formed. An upper portion of the upper contact layer 450 may be planarized through a CMP process.

In example embodiments, the upper contact layer 450 may include, for example, a metal such as tungsten.

A first hole 470 may be formed by etching a portion of the upper contact layer 450 formed on the second region II of the substrate 100.

The first hole 470 may be formed by removing an upper portion of the upper contact layer 450 formed on the second region II of the substrate 100, an upper portion of the first capping pattern 295, and upper portions of the first and fifth spacers 315 and 375 to expose the upper surface of the third spacer 340.

As the first hole 470 is formed, the upper contact layer 450 on the second region II of the substrate 100 may be converted into an upper contact plug 455. The upper contact plug 455 may be on the lower contact plug 405. In example embodiments, the upper contact plug 455 may be formed in plurality to be spaced apart from each other along each first and second direction and arranged in a honeycomb shape when viewed from the top. Each upper contact plug 455 may have, for example, a circular, elliptical, or polygonal shape, when viewed from the top.

The lower contact plug 405 and the upper contact plugs 455 may be (e.g., sequentially) stacked on the second region II of the substrate 100 to form a first contact plug structure.

Thereafter, third and fourth interlayer insulation layers 480 and 490 (e.g., sequentially) stacked on the first hole 470 formed on the second region II of the substrate 100 and the third capping pattern 410 on the second region II may be formed.

Thereafter, a capacitor 540 contacting the upper surface of the upper contact plug 455 may be formed.

After the etch stop layer 500 is formed on the upper contact plug 455 and the third and fourth interlayer insulation layers 480 and 490 and the upper contact plug 455 is exposed, a cylindrical lower electrode 510 may be formed on the upper surface of the upper contact plug 455. Alternatively, a pillar-shaped lower electrode 510 may be formed.

The dielectric layer 520 may be formed on the surface of the lower electrode 510 and the etch stop layer 500, and the upper electrode 530 may be formed on the dielectric layer 520, thereby forming capacitors 540 each including the lower electrode 510, the dielectric layer 520, and the upper electrode 530.

A fifth interlayer insulation layer 550 covering the capacitor 540 may be formed on the second and fourth regions II and IV of the substrate 100. The fifth interlayer insulation layer 550 may include, for example, an oxide such as a silicon oxide.

Upper wires (not shown) may be additionally formed to form semiconductor chips on the first regions I of the substrate 100, respectively.

The semiconductor device may be fabricated by separating the semiconductor chips respectively formed on the first regions I of the substrate 100 from each other through a dicing process or a sawing process.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a substrate;
a chip region in the substrate;
a scribe lane region in the substrate;
first active patterns in the chip region;
a first device isolation pattern on the first active patterns;
second active patterns in the scribe lane region; and
a second device isolation pattern on the second active patterns,
wherein the scribe lane region is adjacent to the chip region,
wherein the first device isolation pattern includes a first device isolation material,
wherein the second device isolation pattern includes a second device isolation material, and
wherein the second device isolation material is different from the first device isolation material.

2. The semiconductor device of claim 1, wherein the first device isolation material has a first etching rate,
wherein the second device isolation material has a second etching rate, and
wherein the first etching rate is different from the second etching rate.

3. The semiconductor device of claim 2, wherein the second etching rate is less than or equal to 0.1 times of the first etching rate.

4. The semiconductor device of claim 1, wherein the first device isolation material includes silicon oxide, and
wherein the second device isolation material includes silicon nitride, silicon carbon nitride, silicon boron nitride, silicon carbon boron nitride, polysilicon, doped polysilicon, and/or a mixture thereof.

5. The semiconductor device of claim 1, further comprising:
bit line structures in the chip region; and
key structures in the scribe lane region.

6. The semiconductor device of claim 5, wherein the bit line structures include a first conductive structure, a first barrier pattern, a first metal pattern, and a first capping pattern which are stacked on the substrate.

7. The semiconductor device of claim 6, wherein the key structures include an insulation pattern, a second conductive structure, a second barrier pattern, a second metal pattern, and a second capping pattern which are stacked on the substrate.

8. The semiconductor device of claim 5, wherein the bit line structures are spaced apart from each other by a first width in a first direction parallel to an upper surface of the substrate and extend in a second direction that intersects the first direction.

9. The semiconductor device of claim 8, wherein the key structures are spaced apart from each other by a second width in the first direction parallel to the upper surface of the substrate and extend in the second direction.

10. The semiconductor device of claim 9, wherein the second width is greater than the first width.

11. A semiconductor device, comprising:
a substrate that has a chip region and a scribe lane region that surrounds the chip region in a plan view,
wherein the chip region includes first active patterns, a first device isolation pattern on the first active patterns, and first gate structures on respective ones of the first active patterns and on the first device isolation pattern,
wherein the scribe lane region includes second active patterns and a second device isolation pattern on the second active patterns,
wherein the first device isolation pattern includes a first device isolation material,
wherein the second device isolation pattern includes a second device isolation material, and
wherein the second device isolation material has an etch selectivity with respect to the first device isolation material.

12. The semiconductor device of claim 11, wherein the first gate structures each includes a first gate insulation layer on the first active patterns and the substrate, a first gate electrode on the first gate insulation layer, and a first gate mask on the first gate electrode.

13. The semiconductor device of claim 11, wherein the first gate structures extend in a first direction parallel to an upper surface of the substrate and are spaced apart from each other in a second direction that intersects the first direction.

14. A semiconductor device, comprising:
a substrate that has a chip region, and a scribe lane region that surrounds the chip region in a plan view;
bit line structures on the chip region; and
key structures on the scribe lane region,
wherein the chip region includes first active patterns, a first device isolation pattern between the first active patterns, and first gate structures on respective ones of the first active patterns and on the first device isolation pattern,
wherein the scribe lane region includes second active patterns and a second device isolation pattern between the second active patterns,
wherein the first device isolation pattern includes a first device isolation material,
wherein the second device isolation pattern includes a second device isolation material, and
wherein the second device isolation material has an etch selectivity with respect to the first device isolation material.

15. The semiconductor device of claim 14, wherein the bit line structures are spaced apart from each other by a first width in a first direction parallel to an upper surface of the substrate and extend in a second direction that intersects the first direction.

16. The semiconductor device of claim 14, wherein the key structures are spaced apart from each other by a second width in a first direction parallel to an upper surface of the substrate and extend in a second direction that intersects the first direction.

17. The semiconductor device of claim 14, wherein the first gate structures extend in a first direction parallel to an upper surface of the substrate and are spaced apart from each other in a second direction that intersects the first direction.

18. The semiconductor device of claim 14, further comprising:
a lower contact plug on a respective one of the first active patterns and the first device isolation pattern between the bit line structures; and
an upper contact plug on the lower contact plug.

19. The semiconductor device of claim 18, further comprising:
a fill pattern on the second device isolation pattern between the key structures; and
an upper contact layer on the second active patterns and the key structures.

20. The semiconductor device of claim 19, further comprising:
a capacitor on the upper contact plug, wherein the capacitor includes a lower electrode on the upper contact plug, a dielectric layer on the lower electrode, and an upper electrode on the dielectric layer.
